(19) United States
(12) Patent Application Publication
(10) Pub. No.: US 2024/0179860 A1
(43) Pub. Date: May 30, 2024

(54) ELECTRONIC DEVICE AND METHOD FOR PROVIDING THE SAME

(71) Applicant: Samsung Display Co., Ltd., Yongin-si (KR)

(72) Inventors: BYUNGHOON KIM, Yongin-si (KR); YONG-HOON KWON, Yongin-si (KR); TAEOH KIM, Yongin-si (KR)

(21) Appl. No.: 18/491,900

(22) Filed: Oct. 23, 2023

(30) Foreign Application Priority Data
Nov. 29, 2022 (KR) 10-2022-0162989

(51) Int. Cl. H05K 5/02

(52) U.S. Cl. CPC H05K 5/0217

(57) ABSTRACT

An electronic device includes an electronic module, a display panel including a second region corresponding to the electronic module and adjacent to a first region, and a lower member overlapping the first region. The lower member includes a functional layer corresponding to the first region, and an adhesive layer corresponding to the first and second regions. The adhesive layer includes a first adhesive portion defining a first lower surface of the adhesive layer which overlaps the first region of the display panel, a second adhesive portion which defines a second lower surface of the adhesive layer which overlaps the second region of the display panel, each of the first and second lower surfaces having hydrophobicity, and the hydrophobicity of the first lower surface of the first adhesive portion being lower than the hydrophobicity of the second lower surface of the second adhesive portion.

This application claims priority to Korean Patent Application No. 10-2022-0162989, filed on Nov. 29, 2022, and all the benefits accruing therefrom under 35 U.S.C. § 119, the entire contents of which are hereby incorporated by reference.

### BACKGROUND

### (1) Field

The present disclosure herein relates to an electronic device and a method for manufacturing (or providing) the same. More particularly, the present disclosure herein relates to an electronic device having increased manufacturing efficiency and a method for manufacturing the same.

### (2) Description of the Related Art

Electronic devices may be devices composed of various electronic components, such as display panels that display images, and electronic modules that serve various functions. The display panels include light emitting elements that generate light such as for displaying an image.

The electronic modules may include cameras, infrared sensors, proximity sensors, and the like. The electronic modules may be placed below the display panels. The display panels may involve a region having higher light transmittance than another region thereof. The electronic modules may receive or output light signals through the region having high transmittance.

### SUMMARY

The present disclosure provides an electronic device in which a lower member of a display panel is easily manufactured and a method for manufacturing the same.

An embodiment of the invention provides an electronic device including a display panel including a first region and a second region adjacent to the first region, a lower member overlapping the first region and disposed below the display panel, and an electronic module overlapping the second region and disposed below the display panel, where the lower member includes an adhesive layer including a first adhesive portion overlapping the first region and a second adhesive portion overlapping the second region, and disposed below the display panel, and a functional layer disposed below the first adhesive portion, and a hydrophobicity of a first lower surface of the first adhesive portion is lower than a hydrophobicity of a second lower surface of the second adhesive portion.

In an embodiment, a surface roughness of the first lower surface of the first adhesive portion may be lower than a surface roughness of the second lower surface of the second adhesive portion. In an embodiment, fine irregularities may be defined on the second lower surface.

In an embodiment, the functional layer may not overlap the second region. In an embodiment, the functional layer may be directly disposed below the first adhesive portion.

In an embodiment, the electronic module may be a camera module or a sensor module.

In an embodiment of the invention, an electronic device includes a display panel, an adhesive layer disposed below the display panel, a functional layer disposed below the adhesive layer, and an electronic module disposed below the adhesive layer and spaced apart from the functional layer, where at least one hole corresponding to the electronic module is defined in the functional layer, the adhesive layer includes a hole adhesive portion overlapping the hole, and fine irregularities are defined on a lower surface of the hole adhesive portion.

In an embodiment of the invention, a method for manufacturing an electronic device including a display panel, a lower member disposed below the display panel, and an electronic module disposed below the display panel includes providing the display panel including a first region and a second region adjacent to the first region and corresponding to the electronic module, and forming the lower member below the display panel, where the forming of the lower member includes forming a preliminary adhesive layer including a first adhesive portion overlapping the first region and a preliminary adhesive portion overlapping the second region below the display panel, hydrophobically treating a lower surface of the preliminary adhesive portion to form a second adhesive portion, and forming a functional layer below the first adhesive portion.

In an embodiment, the forming of the second adhesive portion may include irradiating the lower surface of the preliminary adhesive portion with a laser.

In an embodiment, the forming of the second adhesive portion may include forming fine irregularities on the lower surface of the preliminary adhesive portion.

In an embodiment, a material included in the first adhesive portion may be the same as a material included in the preliminary adhesive portion.

In an embodiment, a hydrophobicity of a lower surface of the second adhesive portion may be lower than a hydrophobicity of the lower surface of the preliminary adhesive portion.

In an embodiment, a surface roughness of a lower surface of the second adhesive portion may be greater than a surface roughness of the lower surface of the preliminary adhesive portion.

In an embodiment, in the forming of the functional layer, the functional layer may be formed on a lower surface of the first adhesive portion and may not be formed on a lower surface of the second adhesive portion.

In an embodiment, the forming of the functional layer may include forming a preliminary functional layer below the first adhesive portion, and curing the preliminary functional layer.

In an embodiment, the forming of the preliminary functional layer may include coating the lower surface of the first adhesive portion with the preliminary functional layer.

In an embodiment, in the forming of the preliminary functional layer, the preliminary functional layer may be provided in a liquid state.

In an embodiment, a hydrophobicity of an upper surface of the preliminary functional layer may be lower than a hydrophobicity of a lower surface of the second adhesive portion.

In an embodiment, the curing of the preliminary functional layer may include light curing or thermal curing.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device according to an embodiment of the invention;

FIG. 2 is an exploded perspective view of an electronic device according to an embodiment of the invention;

FIG. 3 is a cross-sectional view of an electronic device according to an embodiment of the invention;

FIG. 4 is a cross-sectional view of a display panel according to an embodiment of the invention;

FIGS. 5A and 5B are each an enlarged cross-sectional view of an electronic device according to an embodiment of the invention;

FIGS. 6A and 6B are flowcharts showing a method for manufacturing or providing an electronic device according to an embodiment of the invention; and

FIG. 7A to 7E are each an enlarged cross-sectional view of respective processes in a method for manufacturing or providing an electronic device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element (or a region, a layer, a portion, or the like) is referred to as being related to another element such as being “on”, “connected to” or “coupled to” another element, it can be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents.

The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure.

The terminology used herein is for the purpose of describing particular embodiments only and is not intended to be limiting. As used herein, “a”, “an,” “the,” and “at least one” do not denote a limitation of quantity, and are intended to include the plural forms as well, unless the context clearly indicates otherwise. Within the Figures and the text of the disclosure, a reference number indicating a singular form of an element may also be used to reference a plurality of the singular element.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which the present disclosure belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the invention will be described with reference to the accompanying drawings.

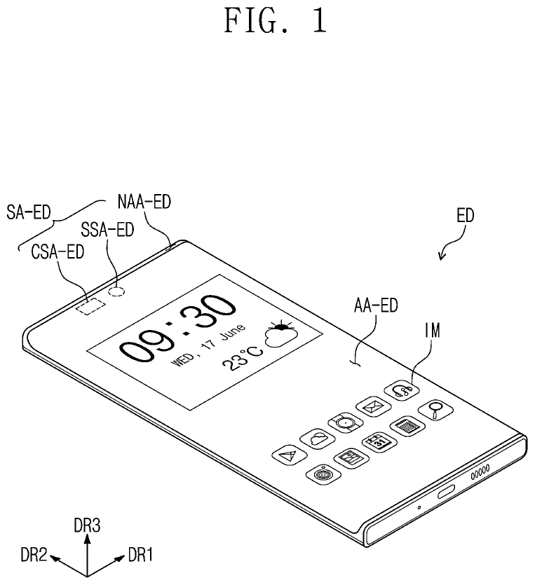

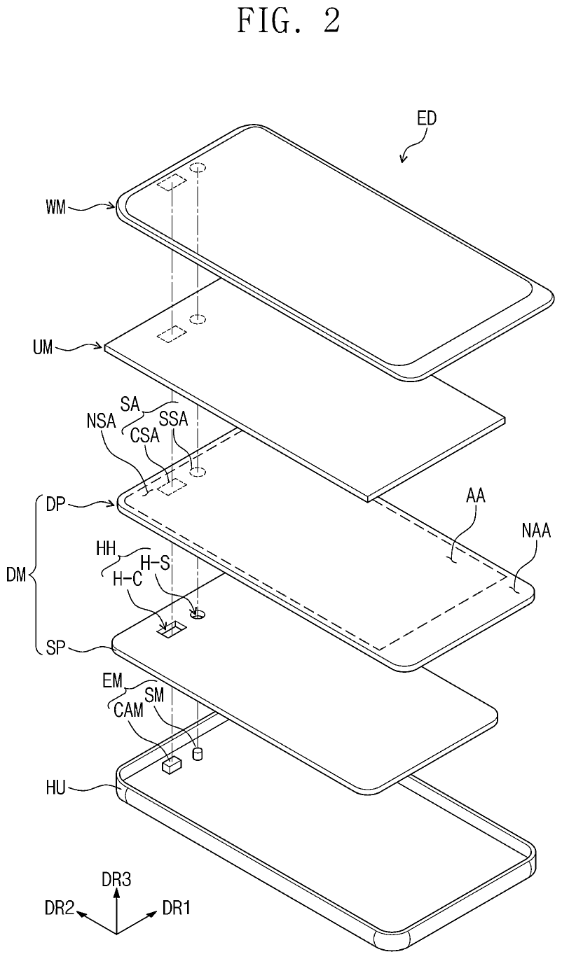

FIG. 1 is a perspective view of an electronic device ED according to an embodiment of the invention. FIG. 2 is an exploded perspective view of an electronic device ED according to an embodiment of the invention.

An electronic device ED of an embodiment may be a device activated according to electrical signals. For example, the electronic device ED may be a mobile phone, a tablet, a car navigation system, a game console, or a wearable device, but is not limited thereto. In FIG. 1, a mobile phone is shown as an example of the electronic device ED.

The electronic device ED may display an image IM through an active region AA-ED. The active region AA-ED may be disposed in a plane defined by a first direction DR1 and a second direction DR2 which cross each other. The active region AA-ED may further include a curved surface bent from at least one side of the plane defined by the first direction DR1 and the second direction DR2. The electronic device ED of an embodiment shown in FIG. 1 is shown to include two curved surfaces each bent from opposing sides of active region AA-ED in the plane defined by the first direction DR1 and the second direction DR2. However, the shape of the active region AA-ED is not limited thereto. For example, the active region AA-ED may include only the plane, and the active region AA-ED may further include curved surfaces each bent from at least two sides of the active region AA-ED in the plane (e.g., four curved surfaces each bent from four sides of the plane).

FIG. 1 and the following drawings show the first to third directions DR1 to DR3, and directions indicated by the first to third directions DR1, DR2, and DR3 described herein are relative concepts, and may thus be changed to other directions.

As used herein, the first direction DR1 and the second direction DR2 herein may cross each other such as to be perpendicular to each other, and the third direction DR3 may be a normal direction to a plane defined by the first direction DR1 and the second direction DR2. As used herein, “on a plane” or “in a plan view” may refer to when a plane defined by the first direction DR1 and the second direction DR2 is viewed along the third direction DR3. A thickness direction may refer to the third direction DR3 which is a normal direction to the plane defined by the first direction DR1 and the second direction DR2.

A sensing region SA-ED may be defined in the electronic device ED and include a plurality of sensing regions. FIG. 1 shows a camera sensing region CSA-ED and a sensor sensing region SSA-ED as an example, but the number of sensing regions SA-ED is not limited thereto. A single sensing region SA-ED or a plurality of three or more sensing regions SA-ED may be defined. In addition, the sensing region SA-ED may be defined in the active region AA-ED to be a portion of the active region AA-ED.

An electronic module EM may overlap the sensing region SA-ED. The electronic module EM may be an electro-optical module which receives an external input transmitted through the sensing region SA-ED from outside the electronic device ED and/, or may provide an output through the sensing region SA-ED to the outside of the electronic device ED. The electronic module EM may receive external inputs delivered through the sensing region SA-ED and/or provide outputs through the sensing region SA-ED. For example, a camera module CAM may overlap the camera sensing region CSA-ED, and a sensor module SM may overlap the sensor sensing region SSA-ED.

The electronic device ED may include the active region AA-ED and the peripheral region NAA-ED which is adjacent to the active region AA-ED. The active region AA-ED may correspond to a display region AA of the display panel DP, which will be described later, and the peripheral region NAA-ED may correspond to a non-display region NAA of the display panel DP.

The peripheral region NAA-ED, as a region that blocks light signals, may be a portion disposed outside the active region AA-ED to surround the active region AA-ED, in the plan view. In an embodiment, the peripheral region NAA-ED may be disposed on a side surface of the electronic device ED instead of a front surface thereof. In an embodiment, the peripheral region NAA-ED may be omitted.

The electronic device ED of an embodiment may include a window WM, a housing HU, an electronic module EM, a display module DM, and an upper member UM.

The electronic device ED according to an embodiment may include a window WM disposed on the display panel DP. The window WM provides or defines an outer surface of the electronic device ED. Although not shown, the window WM may include a base substrate WM-BS and may further include upper functional layers such as an anti-reflection layer, an anti-fingerprint layer, and an optical layer for controlling a phase which are on the base substrate WM-BS.

In the electronic device ED of an embodiment, the upper member UM may be disposed below the window WM and above the display module DM, along the thickness direction (e.g., the third direction DR3). The upper member UM may include an anti-reflection layer and/or an input detection sensor. The anti-reflection layer lowers external light reflectance. The input detection sensor detects external inputs from outside the electronic device ED such as from a user. The upper member UM may further include an adhesive layer bonding the anti-reflection layer and the input detection sensor to each other.

In the electronic device ED of an embodiment, the display module DM may be disposed below the upper member UM. The display module DM may include a display panel DP and a lower member SP.

The display panel DP may include an active region AA displaying the image IM and a non-display region NAA placed adjacent to the active region AA. That is, a front surface of the display panel DP may include the display region AA and the non-display region NAA. The active region AA may be a portion activated according to electrical signals.

The non-display region NAA may be placed adjacent to the active region AA. The non-display region NAA may surround the display region AA. A driving circuit or driving wiring for driving the active region AA, various signal lines or pads for providing electric signals to the active region AA, or electronic elements may be disposed in the non-display region NAA.

The display panel DP may include a first region NSA and a second region SA. The second region SA may be within a planar area of the first region NSA. The second region SA may be a portion overlapping the electronic module EM, and the first region NSA may be a portion disposed to surround at least a portion of the second region SA. That is, the second region SA may be an enclosed area defined by portions of the first region NSA. The second region SA may correspond to (or overlap) the sensing region SA-ED of the electronic device ED. The first region NSA may be a portion corresponding to a region (or planar area) other than a planar area the sensing region SA-ED in the display panel DP.

The second region SA may include a first signal transmission region CSA corresponding to the camera sensing region CSA-ED of the electronic device ED, and a second signal transmission region SSA corresponding to the sensor sensing region SSA-ED of the electronic device ED. Below the display panel DP, the camera module CAM may be disposed to overlap the first signal transmission region CSA, and the sensor module SM may be disposed to overlap the second signal transmission region SSA. Although not shown, a predetermined opening may be defined in one of the second regions SA of the display panel DP in another embodiment as needed. Accordingly, a portion of the display panel DP may be penetrated. That is, the display panel DP may include an inner surface which defines the predetermined opening. The opening may penetrate an entirety of a thickness or a partial thickness of the display panel DP.

Although FIG. 2 shows that the second region SA includes the first signal transmission region CSA and the second signal transmission region SSA as an example, the number of second regions SA is not limited thereto, and in the display panel DP, a single second region SA or a plurality of three or more second regions SA may be defined. In FIG. 2, a planar shape of the second region SA is shown as a circle or a rectangle, but the planar shape of the second region SA is not limited thereto, and may be variously defined as needed.

When viewed on a plane, the second region SA may be smaller in size than the first region NSA, that is, may have a smaller planar area than the first region NSA. The first region NSA may have a transmittance (e.g., a light transmittance) different from that of the second region SA. The second region SA may have a transmittance greater than that of the first region NSA.

In the display panel DP according to an embodiment, a portion of a driving circuit or driving wiring for driving a pixel (not shown) disposed in the second region SA may be disposed in the non-display region NAA and/or in a portion of the first region NSA adjacent to (e.g., closest to or meeting) the second region SA. Accordingly, the wiring density in the second region SA may be lower than the wiring density in the first region NSA. However, the embodiment of the invention is not limited thereto, and the wiring density in the second region SA and the wiring density in the first region NSA may be substantially equal.

The display panel DP may include a light emitting element layer DP-ED (see FIG. 4) including an organic light emitting element, a quantum dot light emitting element, a micro LED light emitting element, or a nano LED light emitting element. The light emitting element layer DP-ED (see FIG. 4) may be configured to substantially generate images.

The lower member SP may be disposed below the display panel DP. The lower member SP may be a member that supports the display panel DP and serves a heat dissipation function for dissipating heat generated from the display panel DP.

In the electronic device ED according to an embodiment, the electronic module EM may be an electronic component outputting or receiving light signals. For example, the electronic module EM may include a camera module CAM and a sensor module SM. The camera module CAM may receive external light through the camera sensing region CSA-ED to capture external images. In addition, the sensor module SM may be a sensor such as a proximity sensor or an infrared light emitting sensor that outputs or receives external light through the sensor sensing region SSA-ED.

In addition, the electronic device ED of an embodiment may include a housing HU disposed below the electronic module EM. The electronic module EM and the display panel DP may be accommodated in the housing HU. In the electronic device ED according to an embodiment, the window WM and the housing HU may combine together to form an exterior of the electronic device ED.

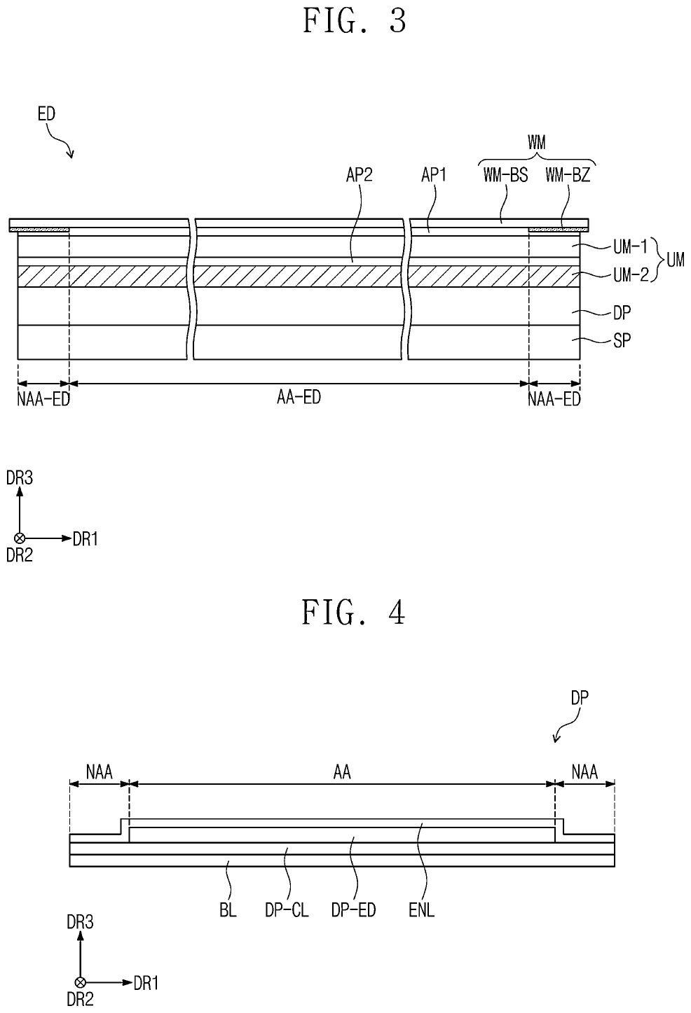

FIG. 3 is a cross-sectional view showing some components of an electronic device ED according to an embodiment of the invention.

Referring to FIG. 3, the electronic device ED according to an embodiment of the invention may include a window WM, an upper member UM, a display panel DP, and a lower member SP. In an embodiment, the window WM may cover a front surface of the display panel DP. The window WM may include a base substrate WM-BS and a bezel pattern WM-BZ. The base substrate WM-BS includes a transparent base layer such as a glass substrate or a transparent film. The bezel pattern WM-BZ may have a multilayer structure. The multilayer structure may include a colored color layer and a black light blocking layer. The colored color layer and the black light blocking layer may be formed (or provided) through deposition, printing, and coating processes. The bezel pattern WM-BZ may be omitted from the window WM and may be formed on the upper member UM instead of the base substrate WM-BS.

In an embodiment, the upper member UM includes an anti-reflection layer UM-1 and an input sensor UM-2. As shown in FIG. 3, the window WM and the anti-reflection layer UM-1 may be bonded through a first adhesive layer AP1, and the input sensor UM-2 may be bonded through a second adhesive layer AP2.

The anti-reflection layer UM-1 may reduce external light reflectance. For example, the anti-reflection layer UM-1 may include a retarder and/or a polarizer. The anti-reflection layer UM-1 may include a polarizing film or color filters. The color filters may have a predetermined arrangement. The arrangement of the color filters may be determined in consideration of the emission colors of pixels included in the display panel DP. The anti-reflection layer UM-1 may further include a division layer adjacent to the color filters.

The input sensor UM-2 may include a plurality of sensing electrodes (not shown) for sensing external inputs, trace lines (not shown) connected to the plurality of sensing electrodes, and an inorganic layer and/or an organic layer for insulating/protecting the plurality of sensing electrodes or trace lines. The input sensor UM-2 may be a capacitance sensor, but is not particularly limited thereto.

The input sensor UM-2 may be directly formed on a thin film encapsulation layer through a continuous process when the display panel DP is manufactured or provided. However, the embodiment of the invention is not limited thereto, and the input sensor UM-2 is manufactured as a panel separate from the display panel DP, and may be bonded to the display panel DP through an adhesive layer.

FIG. 4 is a cross-sectional view of a display panel DP according to an embodiment.

In an embodiment, the display panel DP includes a base layer BL, a circuit layer DP-CL disposed on the base layer BL, a light emitting element layer DP-ED, and an encapsulation layer ENL. The base layer BL may include a plastic substrate, a glass substrate, a metal substrate, an organic/inorganic composite material substrate, or the like. For example, the base layer BL may include at least one polyimide layer.

The circuit layer DP-CL includes at least one insulating layer, semiconductor patterns, and conductive patterns. The insulating layer includes at least one inorganic layer and at least one organic layer. The semiconductor patterns and the conductive patterns may constitute signal lines, a pixel driving circuit, and a scan driving circuit. In addition, the circuit layer DP-CL may include a rear metal layer.

The light emitting element layer DP-ED includes a display element, for example, a light emitting element. For example, the light emitting element may be an organic light emitting element, a quantum dot light emitting element, a micro LED light emitting element, or a nano LED light emitting element. The light emitting element layer DP-ED may further include an organic layer such as a pixel defining film.

The light emitting element layer DP-ED may be disposed in the display region AA. The non-display region NAA may be disposed outside the display region AA in the plan view to surround the display region AA, and a light emitting element may not be disposed in the non-display region NAA.

The encapsulation layer ENL may be disposed on the light emitting element layer DP-ED to cover the light emitting element layer DP-ED. The encapsulation layer ENL may be disposed on the circuit layer DP-CL to encapsulate the light emitting element layer DP-ED. The encapsulation layer ENL may be a thin film encapsulation layer including a plurality of organic thin films and inorganic thin films. The encapsulation layer ENL may include a thin film encapsulation layer having a stack structure of an inorganic layer/organic layer/inorganic layer. The stack structure of the encapsulation layer ENL is not particularly limited.

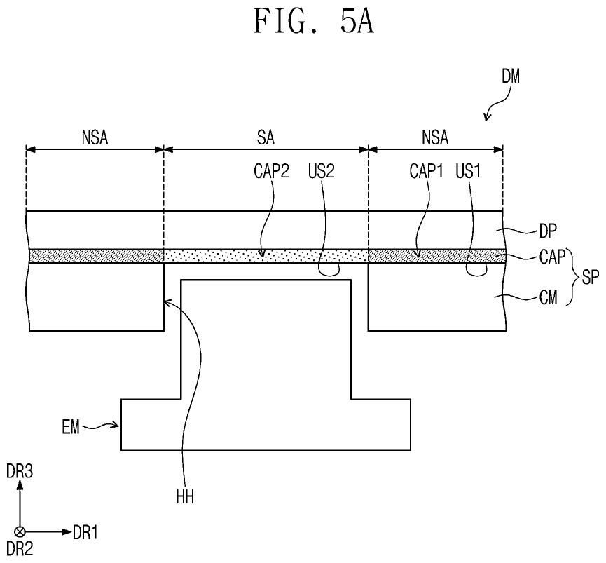

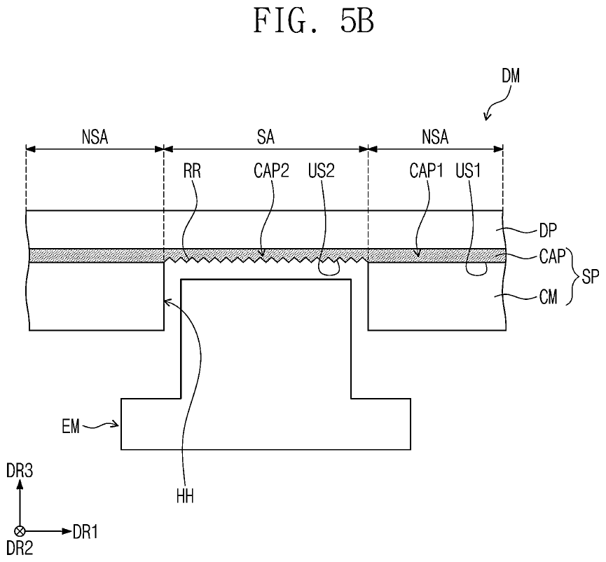

FIGS. 5A and 5B are cross-sectional views of an embodiment showing details of a display module DM and an electronic module EM, which are each a component of an electronic device ED. FIG. 5B shows an embodiment in which fine irregularities RR are included in a portion of an adhesive layer CAP in the display module DM in detail.

Referring to FIGS. 5A and 5B, an electronic device ED according to an embodiment of the invention may include a display module DM and an electronic module EM. The electronic module EM which outputs a signal to or receives a signal from outside of the electronic device ED is spaced apart from the functional layer CM and/or the adhesive layer CAP. A gap may be defined between the electronic module EM and surfaces of the functional layer CM and the adhesive layer CAP which are closest to the electronic module EM. The surfaces may include a lower surface portion of the adhesive layer CAP and inner side surfaces of the functional layer CM.

A hole HH may be defined in the display module DM. An inner surface of the display module DM may define the hole HH. The hole HH may be defined in a region corresponding to the electronic module EM. The hole HH may be defined in a portion of the display module DM, which overlaps the second region SA. The hole HH may have a center, and the first region NSA may be adjacent to the second region SA in a radial direction from the center of the hole HH. In an embodiment, a single one of the hole HH or a plurality of holes HH of the display module DM may be defined by various layers of the display module DM. The hole HH may be a sensor hole H-S or a camera hole H-C described above with reference to FIG. 2. The hole HH may be an enclosed shape in the plan view, such as being defined by portions of the respective panel, layer or component, without being limited thereto. The enclosed hole or the enclosed opening may be surrounded by a portion of the respective panel, layer or component in the plan view, such as to be spaced apart from an outer edge of such panel, layer or component.

In FIGS. 5A and 5B, it is shown that the hole HH as a predetermined opening of the display module DM is defined only in a lower member SP, but the embodiment of the invention is not limited thereto, and a predetermined opening may be additionally defined in a respective adhesive layer, the display panel DP, etc. as needed. Alternatively, some of the plurality of holes HH may be defined only in the lower member SP, and the other holes HH may be defined in both the lower member SP and the display panel DP. A respective hole among the plurality of holes HH may extend into a layer for an entire thickness or a partial thickness thereof. In FIGS. 5A and 5B the hole HH is extended through a partial thickness of the lower member SP and exposes the adhesive layer CAP to outside the lower member SP. Accordingly, the functions of each of the electronic modules EM according to an embodiment of the invention may be performed.

The hole HH may overlap the electronic module EM. At least a portion of the electronic module EM may be inserted or extended into the hole HH. For example, the electronic module EM may be a camera module CAM including a lens, which is placed adjacent to the display panel DP. In an embodiment, the lens of a camera module CAM may be inserted or extended into the hole HH.

The display module DM may include a display panel DP and a lower member SP. The display module DM may be formed of or include a display panel DP together with a lower member SP. The lower member SP may be directly disposed below the display panel DP. Unlike what is shown in the drawings, the display module DM may further include a lower display panel protection layer between the display panel DP and the lower member SP. The lower display panel protection layer may serve to protect a lower side of the display panel DP from shocks.

The lower member SP includes an adhesive layer CAP and a functional layer CM. The lower member SP may include an adhesive layer CAP disposed below the display panel DP and a functional layer CM which is disposed below the adhesive layer CAP. That is, the adhesive layer CAP may be disposed between the display panel DP and the functional layer CM and ma bond the display panel DP to the functional layer CM. The lower member SP may be formed of or include the adhesive layer CAP together with the functional layer CM.

The adhesive layer CAP may be directly disposed below the display panel DP. That is, the adhesive layer CAP may contact the display panel DP such as to form an interface with the display panel DP. The adhesive layer CAP may bond the display panel DP and the functional layer CM to each other. An inner surface of the functional layer CM defines the hole HH, together with a portion of the adhesive layer CAP.

The adhesive layer CAP may include a first adhesive portion CAP1 disposed to overlap or correspond to the first region NSA and a second adhesive portion CAP2 which is disposed to overlap or correspond to the second region SA. The adhesive layer CAP has a lower surface which is furthest from the display panel DP and defined at both the first region NSA and at the second region SA. The lower surface may have a hydrophobicity at each of the first region NSA and the second region SA.

The hydrophobicity of a first lower surface US1 of the first adhesive portion CAP1 is lower than the hydrophobicity of a second lower surface US2 of the second adhesive portion CAP2. The first lower surface US1 is a surface of the first adhesive portion CAP1 which is opposite to the display panel DP, and the second lower surface US2 is a surface of the second adhesive portion CAP2 which is opposite to the display panel DP, among portions of the lower surface of the adhesive layer CAP.

As used herein, ‘high hydrophobicity’ may indicate that a contact angle of water with respect to a specific layer or a surface is relatively large, and ‘low hydrophobicity’ may indicate that a contact angle of water with respect to a specific layer or a surface is relatively small (or smaller than the ‘high hydrophobicity’ surface). That is, a contact angle of water with respect to the first lower surface US1 of the first adhesive portion CAP1 which has the hydrophobicity lower than the hydrophobicity of the second lower surface US2 may be smaller than a contact angle of water with respect to the second lower surface US2 of the second adhesive portion CAP2. In an embodiment, for example, the contact angle of the second lower surface US2 with respect to water may be about 90 degrees)(° to about 170°. For example, the contact angle of the second lower surface US2 with respect to water is about 150° to about 170°, and the second lower surface US2 may thus have superhydrophobic properties.

Accordingly, in an embodiment, the functional layer CM may not be disposed below the second adhesive portion CAP2. As not being disposed below or corresponding to the second adhesive portion CAP2, a solid portion or material portion of the functional layer CM may be non-overlapping or adjacent to (or spaced apart from) the second adhesive portion CAP2 in a direction along the display panel DP.

The first adhesive portion CAP1 and the second adhesive portion CAP2 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto.

Referring to FIG. 5A, the hydrophobicity of the first adhesive portion CAP1 may be different from the hydrophobicity of the second adhesive portion CAP2. When manufacturing or providing the electronic device ED according to an embodiment of the invention, the first adhesive portion CAP1 and the second adhesive portion CAP2 may be formed of the same material or from a same material layer, and then a hydrophobic treatment may be performed on the second adhesive portion CAP2 of the same material layer to define the different hydrophobicities within the single layer of the adhesive layer CAP. The hydrophobic treatment is reflected by the different shading patterns in FIG. 5A. Accordingly, the hydrophobicity of the first lower surface US1 of the first adhesive portion CAP1 may be lower than the hydrophobicity of the second lower surface US2 of the second adhesive portion CAP2.

Referring to FIG. 5B, fine irregularities RR may be defined on the second lower surface US2 of the second adhesive portion CAP2 in an embodiment of the invention. That is, the second adhesive portion CAP2 may have a structure of irregularities or an uneven surface from porous or solid nanoparticles of the adhesive layer CAP at the second adhesive portion CAP2. Alternatively, the second adhesive portion CAP2 may have a structure of irregularities in which a nano size and a micro size structures are combined. Such irregularities may define a surface roughness of the adhesive layer CAP at the various portions thereof. In an embodiment, for example, the electronic device ED may include a functional layer CM facing the display panel DP, the functional layer defining a hole HH corresponding to the electronic module EM, and an adhesive layer CAP which bonds the display panel DP to the functional layer CM. The adhesive layer CAP includes a hole adhesive portion (e.g., the second adhesive portion CAP2) exposed to outside the functional layer CM by the hole HH, and the hole adhesive portion having irregularities (e.g., the fine irregularities RR) defining a surface roughness different from a surface roughness of a non-hole adhesive portion (e.g., the first adhesive portion CAP1).

Accordingly, a surface roughness of the second lower surface US2 of the second adhesive portion CAP2 may be greater than a surface roughness of the first lower surface US1 of the first adhesive portion CAP1. As the second adhesive portion CAP2 includes the fine irregularities RR, the contact angle of water with respect to the second adhesive portion CAP2 is increased, so that the hydrophobicity of the second adhesive portion CAP2 is relatively greater than the hydrophobicity of the first adhesive portion CAP1.

The adhesive layer CAP may include a transparent material. The adhesive layer CAP may include a pressure sensitive adhesive film (PSA) or an optically clear adhesive (OCA). Accordingly, light generated inside or outside an electronic device ED, and then respectively emitted or received, may pass through the adhesive layer CAP.

Referring to FIGS. 5A and 5B, the functional layer CM may be disposed below the adhesive layer CAP. The functional layer CM may be directly disposed below the adhesive layer CAP, such as to contact or form an interface therewith. The functional layer CM may be disposed to overlap the first region NSA and may be disposed not to overlap the second region SA. That is, the functional layer CM may be disposed below the first adhesive portion CAP1 and may not be disposed below the second adhesive portion CAP2. The hole HH described above may be defined in a portion of the second region SA where the functional layer CM is not disposed, where an inner side surface of the functional layer CM may define the hole HH. That is, the functional layer CM may be disconnected at the second region SA, without being limited thereto. Accordingly, the functional layer CM may non-overlap the electronic module EM when viewed on a plane.

The functional layer CM may serve multiple functions within an electronic device. For example, the functional layer CM may serve a plurality of functions such as supporting, heat-dissipating, and shielding an electronic device ED (see FIG. 1). The functional layer CM may support the display panel DP as a support layer. The functional layer CM may protect the display panel DP and the electronic module EM from physical impact applied from the outside of the electronic device ED to define an impact-absorbing layer (see FIG. 1). The functional layer CM may serve a heat dissipating function for dissipating heat generated from the display panel DP or the like to define a heat-dissipation layer. The functional layer CM may have a function such as electromagnetic wave shielding to serve as an electromagnetic-shielding layer. However, the embodiment of the invention is not limited thereto, and the functional layer CM may additionally serve other functions in the electronic device according to features such as thickness and material of the functional layer CM.

The functional layer CM may be a single layer. Alternatively, unlike what is shown in FIGS. 5A and 5B, in an embodiment of the invention, the functional layer CM may include a plurality of layers, and the plurality of layers may respectively serve a function such as supporting, heat-dissipating, and shielding an electronic device.

The functional layer CM may include a hydrophilic material. That is, a contact angle of water with respect to an upper surface of the functional layer CM may be small. Accordingly, the functional layer CM may not be disposed on the second lower surface US2 of the second adhesive portion CAP2 having relatively high hydrophobicity. In an embodiment, the functional layer CM may be disposed on the adhesive layer CAP at the first lower surface US1 of the first adhesive portion CAP1 and may not be disposed on the adhesive layer CAP at the second lower surface US2 of the second adhesive portion CAP2. Accordingly, at least one hole HH corresponding to the second region SA may be defined in or by the functional layer CM.

Hereinafter, a method for manufacturing (or providing) an electronic device ED according to an embodiment will be described with reference to drawings. In the description of the method for manufacturing or providing an electronic device ED according to an embodiment, overlapping descriptions of the electronic device ED according to an embodiment described above will be omitted.

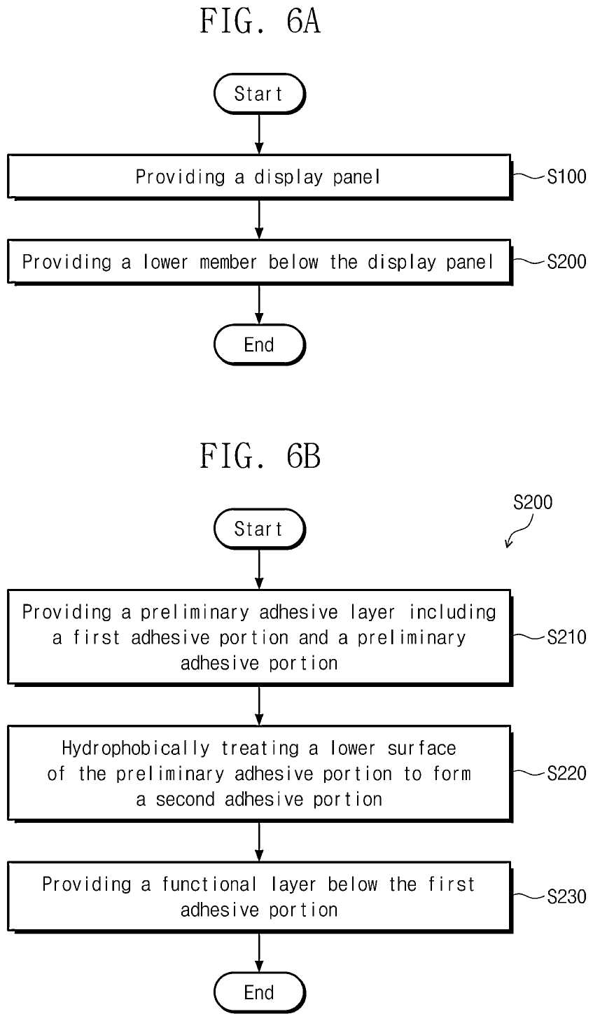

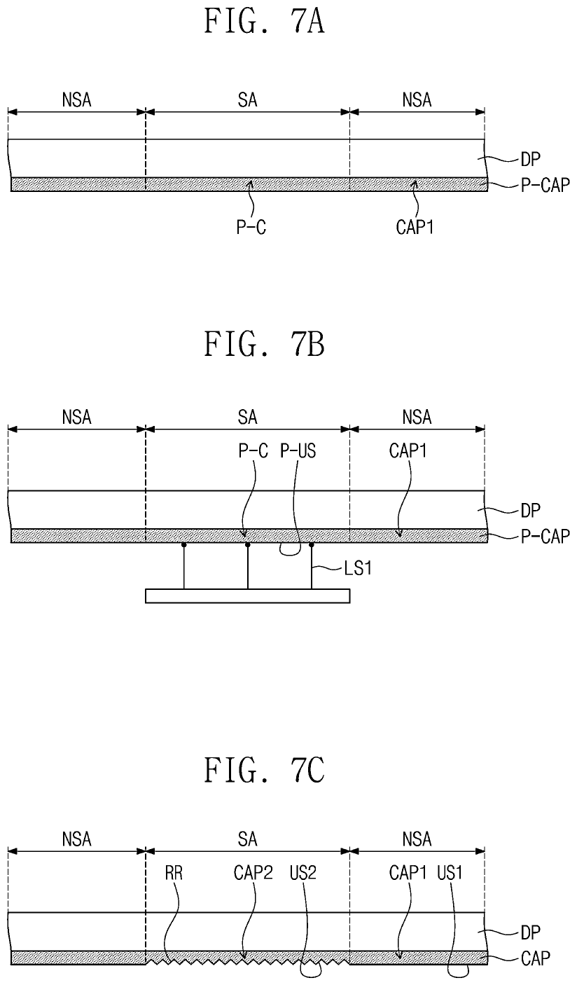

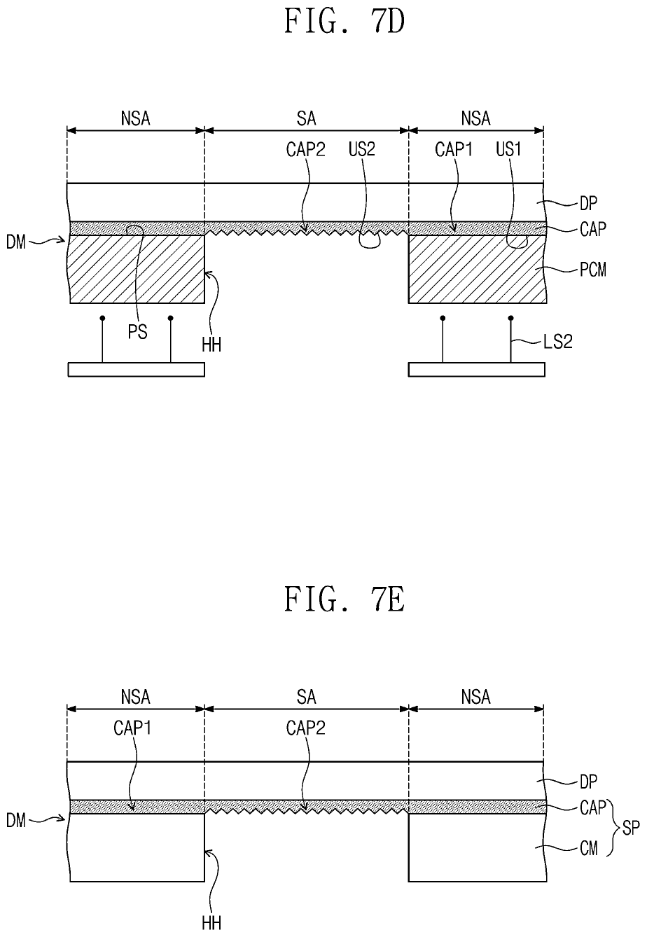

FIGS. 6A and 6B are flowcharts showing a method for manufacturing or providing an electronic device ED according to an embodiment of the invention. FIG. 7A to 7E are enlarged cross-sectional views of various processes in a method for manufacturing or providing an electronic device ED according to an embodiment of the invention.

Referring to FIG. 6A, the method for manufacturing or providing an electronic device ED according to an embodiment of the invention includes providing a display panel DP (S100) and forming (or providing) a lower member SP below the display panel DP (S200). According to FIG. 6B, the forming of a lower member SP below a display panel DP (S200) in the method for manufacturing an electronic device ED according to an embodiment of the invention includes forming a preliminary adhesive layer P-CAP including a first adhesive portion CAP1 and a preliminary adhesive portion P-C adjacent to each other (S210), hydrophobically treating a lower surface of the preliminary adhesive portion P-C to form a second adhesive portion CAP2 (S220), and forming a functional layer CM below the first adhesive portion CAP1 (S230).

Referring to FIG. 7A, the method for manufacturing an electronic device ED according to an embodiment of the invention includes providing a display panel DP. The display panel DP includes a first region NSA and a second region SA. The second region SA extends from the first region NSA and meets the first region NSA at a boundary therebetween, and the electronic module EM in the electronic device ED is disposed to overlap the second region SA, as shown in FIG. 5A.

The method of manufacturing an electronic device ED according to an embodiment of the invention may include forming a preliminary adhesive layer P-CAP below the display panel DP, in both the first region NSA and the second region SA. The preliminary adhesive layer P-CAP may be formed to overlap or correspond to a front surface of the first region NSA and the second region SA, where such front surface may define or include a display surface of the electronic device ED. The preliminary adhesive layer P-CAP may include a first adhesive portion CAP1 overlapping the first region NSA and a preliminary adhesive portion P-C overlapping the second region SA. The first adhesive portion CAP1 and the preliminary adhesive portion P-C may be formed of the same material through a single process. The first adhesive portion CAP1 and the preliminary adhesive portion P-C as respective portions of a same preliminary adhesive layer P-CAP may have a same hydrophobicity, a same surface roughness, etc.

Referring to FIGS. 7B and 7C, the method for manufacturing an electronic device ED according to an embodiment of the invention may include forming an adhesive layer CAP from the preliminary adhesive layer P-CAP, after the forming of the preliminary adhesive layer P-CAP.

Referring to FIG. 7B, the forming or providing of the adhesive layer CAP may include hydrophobically treating the preliminary adhesive portion P-C at a preliminary lower surface P-US thereof to form a second adhesive portion CAP2. The hydrophobically treating the preliminary adhesive portion P-C at the preliminary lower surface P-US may provide a hydrophobicity of the first adhesive portion CAP1 which is different from the hydrophobicity of the second adhesive portion CAP2. The preliminary lower surface P-US of the preliminary adhesive portion P-C may be hydrophobically treated to form the second adhesive portion CAP2. As used herein, ‘hydrophobic treatment’ may indicate a series of processes for increasing hydrophobicity. That is, when the hydrophobic treatment is performed on a specific layer or a surface of such layer, a contact angle of water with respect to the specific layer or the surface may be increased. In an embodiment, the hydrophobic treatment may solely define the hydrophobicity of the first lower surface US1 of the first adhesive portion CAP1 being lower than the hydrophobicity of the second lower surface US2 of the second adhesive portion CAP2 (see FIG. 5A having the different shadings within the single layer of the adhesive layer CAP).

The forming of the second adhesive portion CAP2 includes hydrophobically treating the preliminary lower surface P-US of the preliminary adhesive portion P-C. The hydrophobic treatment on the preliminary lower surface P-US of the preliminary adhesive portion P-C may include increasing a surface roughness of the preliminary lower surface P-US of the preliminary adhesive portion P-C, without being limited thereto. That is, the surface roughness of the lower surface US2 of the second adhesive portion CAP2 is greater than the surface roughness of the preliminary lower surface P-US of the preliminary adhesive portion P-C, through the hydrophobic treatment on the preliminary lower surface P-US of the preliminary adhesive portion P-C.

Referring to FIG. 7C, the hydrophobic treatment on the preliminary lower surface P-US of the preliminary adhesive portion P-C may include processing the preliminary lower surface P-US of the preliminary adhesive portion P-C to form fine irregularities RR. As the fine irregularities RR are formed in the preliminary adhesive layer P-CAP at the preliminary lower surface US2 of the second adhesive portion CAP2, the surface roughness of the second lower surface US2 may rise. Accordingly, the hydrophobicity of the second lower surface US2 of the second adhesive portion CAP2 may be greater than the hydrophobicity of the first lower surface US1 of the first adhesive portion CAP1.

The hydrophobic treatment on the preliminary lower surface P-US of the preliminary adhesive portion P-C may include irradiating the preliminary lower surface P-US of the preliminary adhesive portion P-C with a laser LS1. The increasing of the surface roughness of the preliminary lower surface P-US of the preliminary adhesive portion P-C may include irradiating the preliminary lower surface P-US of the preliminary adhesive portion P-C with a laser LS1. The fine irregularities RR may be defined on the second adhesive portion CAP2 through the irradiating of the laser LS1. Although not shown, the fine irregularities RR may be defined through plasma treatment using a specific gas or the like. However, the hydrophobic treatment on the preliminary lower surface P-US of the preliminary adhesive portion P-C is not limited to forming irregularities, and may include other processes for increasing the hydrophobicity and/or the surface roughness of the second lower surface US2 of the second adhesive portion CAP2.

Referring to FIGS. 7D and 7E, the method for manufacturing an electronic device ED according to an embodiment of the invention may include forming a functional layer CM below the adhesive layer CAP, after the forming of the adhesive layer CAP having different hydrophobicities from each other. The functional layer CM may be disposed below the first adhesive portion CAP1 and may not be disposed below the second adhesive portion CAP2, that is, may be excluded from the second region SA.

The forming or providing of the functional layer CM may include forming a preliminary functional layer PCM and curing the preliminary functional layer PCM. The hydrophobicity of a preliminary upper surface PS of the preliminary functional layer PCM may be lower than the hydrophobicity of the second lower surface US2 of the second adhesive portion CAP2. The hydrophobicity of the material for forming the preliminary functional layer PCM may be lower than the hydrophobicity of the second lower surface US2 of the second adhesive portion CAP2. That is, the preliminary functional layer PCM may include a hydrophilic material. Accordingly, the preliminary functional layer PCM may not be disposed on the second lower surface US2 of the second adhesive portion CAP2 having a relatively higher hydrophobicity than the first lower surface US1 of the first adhesive portion CAP1.

In the forming of the preliminary functional layer PCM, the hydrophilic material for forming the preliminary functional layer PCM may be provided in a liquid state. As being in a liquid state, the material may be flowable along the adhesive layer CAP, without being limited thereto. The material for forming the preliminary functional layer PCM may include a curable resin. The preliminary functional layer PCM may be formed of or include a photocurable resin or a thermosetting resin. The forming of the preliminary functional layer PCM may include a coating process of coating the material for forming the preliminary functional layer PCM, in a liquid state. The forming of the preliminary functional layer PCM may be performed through at least one of a spin coating method, a slit coating method, a jet printing method, a metal mask printing method, or a screen printing method.

After the forming of the preliminary functional layer PCM, the method for manufacturing an electronic device ED according to an embodiment may include curing the hydrophilic material for forming the preliminary functional layer PCM. That is, the preliminary functional layer PCM including a curable resin may be provided on the adhesive layer CAP and resultingly coated on the second lower surface US2 of the second adhesive portion CAP2 owing to the hydrophobicity differences with the adhesive layer CAP, and then cured.

The curing of the material for forming the preliminary functional layer PCM may include irradiation with light LS2. The preliminary functional layer PCM may be photo-cured through the irradiation with the light LS2. Alternatively, the material for forming the preliminary functional layer PCM may be thermally cured through the irradiation with the light LS2.

Referring to FIG. 7E, cured hydrophilic material may form the solid portions of the functional layer CM at planar areas of the adhesive layer CAP except for the high hydrophobicity region (e.g., the second region SA). While FIGS. 5A and 5B show a cross-section in the first direction DR1 and the third direction DR3 of the second adhesive portion CAP, it is understood that the cross-section may be extended around a periphery of the hole HH in a plan view.

One or more embodiment of an electronic device ED including a display panel DP includes a functional layer CM that serves multiple functions such as shielding, heat-dissipating, and/or supporting the display panel DP. The electronic device ED requires a separate opening in the functional layer CM disposed below the display panel DP to accommodate an electronic module EM such as a sensor or a camera therein. Accordingly, typical electronic devices are manufactured or provided through a process of forming a functional layer CM to non-overlap an electronic module below a display panel DP using a mask or a process of removing a portion of a functional layer which corresponds to an electronic module EM through an etching process, or the like.

In one or more embodiment of an electronic device ED according to an embodiment of the invention, a method for manufacturing or providing an electronic device ED may have a greater efficiency by increasing hydrophobicity on or at a portion of the lower member SP which corresponds to an electronic module EM, particularly by increase hydrophobicity at an adhesive layer cap among a plurality of adhesive layers disposed between a display panel DP and a functional layer CM. Specifically, as a portion of an adhesive layer CAP in a region corresponding to the electronic module EM is hydrophobically treated, a functional layer CM in the region corresponding to the electronic module EM may be non-adhesive with or repelled by such hydrophobically treated area, to be excluded from the electronic module region (e.g., second region SA) of to the display panel DP. Therefore, through one or more embodiment of the method for manufacturing or providing an electronic device ED according to an embodiment of the invention, a process of forming a functional layer CM through a mask to remove material portions thereof, or a separate process for removing a functional layer of a corresponding region of an electronic module, may be obviated. Accordingly, the electronic device ED according to an embodiment of the invention may be easily manufactured and the process may be simplified.

In one or more of an embodiment of an electronic device ED according to an embodiment of the invention, when disposing a lower functional material layer of a display panel DP, a hydrophobic treatment may be differently applied depending on a region or planar area of the lower functional material, resulting in a reduced overall thickness of the electronic device and a simplified process or manufacturing or providing thereof. Through a method for manufacturing an electronic device ED according to an embodiment of the invention, a separate removal process for material portions and the like are not required, and accordingly, process efficiency may be increased.

Although the present disclosure has been described with reference to embodiments of the invention, it will be understood that the invention should not be limited to these embodiments but various changes and modifications can be made by those skilled in the art without departing from the spirit and scope of the present disclosure. Accordingly, the technical scope of the invention is not intended to be limited to the contents set forth in the detailed description of the specification, but is intended to be defined by the appended claims.

What is claimed is:

1. An electronic device comprising:
an electronic module which outputs a signal to or receives a signal from outside of the electronic device;
a display panel including a first region, and a second region which corresponds to the electronic module and is adjacent to the first region; and
a lower member overlapping the first region of the display panel and into which the electronic module extends, the lower member including:
a functional layer corresponding to the first region of the display panel,
an adhesive layer which corresponds to the first region and the second region of the display panel and bonds the functional layer to the display panel, the adhesive layer including:
a first adhesive portion defining a first lower surface of the adhesive layer which overlaps the first region of the display panel,
a second adhesive portion which is adjacent to the first adhesive portion, the second adhesive portion defining a second lower surface of the adhesive layer which overlaps the second region of the display panel,
each of the first lower surface and the second lower surface of the adhesive layer having hydrophobicity, and
the hydrophobicity of the first lower surface of the first adhesive portion being lower than the hydrophobicity of the second lower surface of the second adhesive portion.

2. The electronic device of claim 1, wherein
each of the first lower surface and the second lower surface of the adhesive layer has a surface roughness, and
the surface roughness of the first lower surface of the adhesive layer is lower than the surface roughness of the second lower surface of the adhesive layer.

3. The electronic device of claim 2, wherein the second adhesive portion includes porous or solid particles as irregularities of the second lower surface, the irregularities defining the surface roughness of the second lower surface which is greater than the surface roughness of the first lower surface.

4. The electronic device of claim 1, wherein the functional layer defines a hole corresponding to the second region and the second adhesive portion is exposed to outside the functional layer by the hole.

5. The electronic device of claim 1, wherein the functional layer is directly on the first adhesive portion of the adhesive layer.

6. The electronic device of claim 1, wherein the electronic module comprises a camera module or a sensor module.

7. An electronic device comprising:
an electronic module which outputs a signal to or receives a signal from outside of the electronic device;
a display panel;
a functional layer facing the display panel, the functional layer defining a hole corresponding to the electronic module; and
an adhesive layer which bonds the display panel to the functional layer, the adhesive layer including:
a hole adhesive portion exposed to outside the functional layer by the hole, and
the hole adhesive portion having irregularities defining a surface roughness of the hole adhesive portion which is different from a surface roughness of a non-hole adhesive portion.

8. A method for providing an electronic device, the method comprising:
providing a display panel including a first region, and a second region which corresponds to an electronic module and is adjacent to the first region; and
providing a lower member overlapping the first region of the display panel and into which the electronic module extends, the providing of the lower member comprises:
providing an adhesive layer of the lower member which corresponds to the first region and the second region of the display panel, the providing of the adhesive layer comprising:
providing a preliminary adhesive layer comprising a first adhesive portion overlapping the first region, and a preliminary adhesive portion overlapping the second region, and
hydrophobically treating a lower surface of the preliminary adhesive portion to form a second adhesive portion of the adhesive layer which corresponds to the second region of the display panel, and
providing a functional layer of the lower member which faces the display panel and is bonded to the display panel by the adhesive layer.

9. The method of claim 8, wherein a material included in the first adhesive portion is the same as a material included in the preliminary adhesive portion.

10. The method of claim 8, wherein the forming of the second adhesive portion comprises irradiating the lower surface of the preliminary adhesive portion with a laser.

11. The method of claim 8, wherein the forming of the second adhesive portion comprises providing the lower surface of the preliminary adhesive layer having irregularities.

12. The method of claim 8, wherein a hydrophobicity of a lower surface of the second adhesive portion is lower than a hydrophobicity of the lower surface of the preliminary adhesive portion.

13. The method of claim 8, wherein a surface roughness of a lower surface of the second adhesive portion is greater than a surface roughness of the lower surface of the preliminary adhesive portion.

14. The method of claim 8, wherein the providing of the functional layer comprises the functional layer provided on a lower surface of the first adhesive portion and exposing the second adhesive portion of the adhesive layer to outside the functional layer.

15. The method of claim 8, wherein the providing of the functional layer comprises:
providing a preliminary functional layer on the first adhesive portion of the adhesive layer; and
curing the preliminary functional layer.

16. The method of claim 15, wherein the providing of the preliminary functional layer comprises providing a material of the preliminary functional layer on a lower surface of the first adhesive portion.

17. The method of claim 15, wherein in the providing of the preliminary functional layer, the material of the preliminary functional layer is provided in a liquid state.

18. The method of claim 15, wherein a hydrophobicity of an upper surface of the preliminary functional layer is lower than a hydrophobicity of a lower surface of the second adhesive portion.

19. The method of claim 15, wherein the curing of the preliminary functional layer comprises light curing.

20. The method of claim 15, wherein the curing of the preliminary functional layer comprises thermal curing.
